(19) United States
(12) Patent Application Publication
(10) Pub. No.: US 2022/0181508 A1
(43) Pub. Date: Jun. 9, 2022

(54) DEVICE FOR GENERATING ENERGY FROM AMBIENT LIGHT AND PHOTOVOLTAIC CONVERSION DEVICE

(71) Applicant: Lusoco B.V., EINDHOVEN (NL)

(72) Inventors: Jeroen ter Schiphorst, Hedel (NL); Teunis Jort Lowijs Wagenaar, Duivendrecht (NL)

(21) Appl. No.: 17/441,414

(22) PCT Filed: Mar. 24, 2020
(86) PCT No.: PCT/NL2020/050197

§ 371 Date: Sep. 21, 2021

(30) Foreign Application Priority Data
Mar. 25, 2019 (NL) 2022801

(51) Int. Cl. H01L 31/055; E06B 9/24; H01L 31/048

(52) U.S. Cl. CPC H01L 31/055; E06B 2009/2476; H01L 31/0481; E06B 9/24

(57) ABSTRACT

Device for generating energy from ambient light A device for generating energy from ambient light, particularly sunlight, comprises a transparent panel (15, 16) having frontally a lateral entry surface (A) for ambient light and having laterally an exit surface which is optically coupled to a photovoltaic conversion device (250). An optically active photoluminescent structure (18) is arranged downstream of the entry surface, which is able and configured to emit emission radiation upon excitation by radiation incident thereon. The emission radiation propagates partially via the panel (15, 16) to the exit surface (U) and to the conversion device. The conversion device comprises an associated array of mechanically interconnected photovoltaic modules (200), each comprising one or more photovoltaic cells. The modules (200) are electrically connected between a first conductor (210) on an optically active frontal side and a second conductor (220) on an opposite, back side. Successive modules in the array overlap each other such that a first conductor of one module and a second conductor of a subsequent module make contact with each other.

The present invention relates to a device for generating energy from ambient light, particularly from sunlight, comprising at least one at least substantially transparent panel having on a frontal side a lateral entry surface for ambient light and having laterally of the entry surface, particularly substantially transversely thereof, at least one exit surface which is optically coupled to a photovoltaic conversion device. The invention further relates to a photovoltaic conversion device applied therein or at least applicable therein.

Generating energy from sunlight is taking place on an ever-increasing scale as sustainable energy source. This involves substantially solar panels adapted thereto, densely packed with solar cells. These panels are directed toward the sun and sunlight is captured more or less directly by the solar cells and converted into electrical energy. Although with the ongoing optimization of this technology an increasingly better conversion efficiency can thereby be realized, such panels have the drawback that there is not always enough space available for them, and such panels are often deemed aesthetically unattractive.

An alternative device for generating electricity from ambient light, particularly sunlight, is a so-called luminescent solar concentrator (LSC). Such a device is for instance known from the American patent U.S. Pat. No. 8,969,715. This relates to a panel which behaves as an optical waveguide on which ambient light is incident over a relatively large frontal area. Molecules or atoms in a luminescent structure of luminescent domains lying therebehind become excited thereby. When they drop to a lower energy state, these molecules/atoms emit relatively omnidirectional emission radiation, usually with a longer wavelength than a wavelength of the excitation radiation. At least a part thereof is coupled into the panel and becomes captured therein as a result of a higher refractive index of the panel relative to the surrounding area. Due to total internal reflection within the panel, this part of the radiation eventually reaches an end side surface thereof and exits the panel there. A photovoltaic device which is optically coupled to this exit surface then converts the radiation into electricity.

Although the conversion efficiency of such an LSC device will be smaller than that of a more conventional solar panel, this is largely compensated by the active surface area and the low cost at which LSC devices can be realized. LSC devices can particularly be applied as window in a façade of a building, and thereby cover a considerably larger surface area than is available for solar panels on a roof surface. A combination of both solar panels on a roof surface and LSC devices in the façade is moreover possible. The invention is here particularly suitable for high-rise office buildings and particularly for skyscrapers, which are often manifested with an enormous sun-facing glass façade.

Due to the relatively small available surface area of the exit surface in relation to the frontal surface, it is desirable for the photovoltaic device to utilize this surface area as optimally as possible. This involves not only a conversion efficiency of a photovoltaic cell or cells applied in the photovoltaic device, but also a high density of the cells over this surface, a favourable scalability and a favourable cost price.

The present invention has for its object, among others, to provide a device for generating energy from ambient light, whereby one or more of these objectives can be achieved.

For this purpose a device for generating energy from ambient light has the feature according to the present invention that the conversion device comprises an associated array of mechanically interconnected photovoltaic modules, each comprising one or more photovoltaic cells, a first conductor and a second conductor, that in each of the photovoltaic modules the one or more photovoltaic cells are electrically connected between the first conductor on an optically active frontal side of the relevant module and the second conductor on an opposite, back side of the relevant module, and that successive modules in the array of modules partially overlap each other such that a first conductor of one module and a second conductor of a subsequent module make contact with each other. The photovoltaic device thus comprises a series connection of successive photovoltaic modules which are assembled into a fitting whole in mechanical manner.

On the frontal side the modules have a photovoltaically operative, optically active surface onto which the radiation which will be converted into electricity is incident. Because the subsequent module falls with this surface over (overlaps) the conductor on the back side of the one module, almost no surface area need be lost in longitudinal direction of the device. In a preferred embodiment the photovoltaic device is moreover characterized in that a width of each of the modules is adapted to a width of the at least one exit surface, and that a length of the array of modules is adapted to a length of the at least one exit surface. The surface area of the exit surface is thus likewise utilized optimally, whereby the available and optically active part of the exit surface can be utilized particularly efficiently.

The conversion device according to the invention can be applied along the edge of the at least one panel and thereby capture ambient light, particularly sunlight, and converted into electricity directly. In that case the panel can be a relatively conventional window which is for instance used for entry of daylight into a space of a building and thus contributes to the conversion of sunlight into electricity, for instance for the purpose of supplying power to distributed consumers, such as sensors and actors in a domotics system or other (smart) system for automated building management. A rechargeable power supply can also be replaced thereby in advantageous manner.

For a higher conversion factor the invention can also be applied in a luminescent solar concentrator (LSC). In that case secondary, emission radiation which was obtained from luminescence can also be utilized, in addition to direct solar radiation, for conversion into electricity. A preferred embodiment of the device has for this purpose the feature according to the invention that a photoluminescent structure of photoluminescent domains is arranged between the entry surface and the exit surface, which domains are able and configured to emit emission radiation upon excitation by primary radiation incident thereon, and to couple at least part of this emission radiation optically into the at least one panel, wherein the emission radiation propagates at least partially to the exit surface and to the conversion device due to total internal reflection.

A further preferred embodiment of the device according to the invention is characterized in that each of the modules makes use of a carrier substrate, particularly a flexible carrier film, on which the one or more photovoltaic cells are arranged, that the carrier substrate comprises beyond the one or more photovoltaic cells a contact zone over which the first conductor of the module extends, and that the module overlaps in the contact zone with an adjacent module in the array. Owing to this construction, wherein the carrier substrate provides a contact zone beyond the module, successive modules can be assembled into an interconnected array in particularly practical manner simply by placing a subsequent module with its second conductor on the first conductor of its predecessor located there. A particular embodiment of the device has the feature here that successive modules in the array of modules are mutually stacked at the position of the overlap for the purpose of forming a pressure contact between the first conductor and the second conductor of the successive modules.

In order to protect the modules from ambient factors such as air and water (vapour) a further preferred embodiment of the device according to the invention has the feature that the photovoltaic device comprises a moisture-tight film assembly, comprising an optically clear first barrier film on an optically active side of the array of modules and a second barrier film on an opposite, back side of the array of modules, that the first and second barrier film extend laterally outside the array of modules, particularly all the way around, and are mutually connected at the position of a mutual overlap in order to enclose the array of modules in at least substantially vapour-tight manner. In this context a barrier film is understood to mean a film which protects the modules against entry of water and water vapour in effective manner.

An alternative preferred embodiment has the feature here that the photovoltaic conversion device comprises a moisture-tight film assembly, comprising an optically clear first barrier film on an optically active side of the array of modules and a second barrier film on an opposite, back side of the array of modules, that the array of modules is flanked on either side, and particularly surrounded, by an edge seal and lies enclosed together therewith between the films in order to enclose the array of modules in at least substantially vapour-tight manner.

Particularly good results have been obtained in this respect with a particular embodiment of the device according to the invention, characterized in that each of the films comprises a plastic film, particularly an optically clear polyethylene terephthalate (PET) film on the optically active side and an optically dark polyethylene terephthalate (PET) film on the back side. Thus packaging the modules between a set of barrier films counteracts premature degradation thereof.

In a further particular embodiment, which is characterized in that the barrier films and the array of modules are mutually adhered with interposing of an optically clear and hydrophobic adhesive, this moisture-tightness and protection is strengthened further. The adhesive forms a hydrophobic encapsulant and thereby additional protection for the modules. In that case the stack comprises in succession: the first film->adhesive->modules->adhesive->second film. If a suitable edge seal is provided laterally of the modules, this is also adhered between the films as an additional barrier to moisture.

For an effective protection of the modules a width of the film is important for preventing lateral entry and effect of moisture. With a view hereto, the film is advantageously applied with excess length and width relative to a length and width of the array of modules in order to thus ensure an optimal seal. An optional additional edge seal can then be arranged laterally of the modules between the films and be enclosed together therewith as an additional precaution.

For the purpose of an external electrical connection of the array of photovoltaic modules to an electrical load or storage respective connecting electrodes can be provided thereon. A further preferred embodiment of the device according to the invention has the feature here that a first module in the array of modules and a final module of the array of modules are each provided with a connecting electrode, wherein the connecting electrode of the first module and that of the final module each lie on a back side of the array of modules. The connecting electrodes thus lie on the back side of the whole, roughly in the same, common plane, which is advantageous from a viewpoint of an airtight and watertight seal, for instance between the above described assembly of barrier films.

For a bridging, at one outermost of the photovoltaic modules in the array, from the level of the first conductor to the electrode on the back side a particular embodiment of the device has the feature according to the invention that one of the connecting electrodes is connected via a conductive intermediate body to the first conductor of the module connected thereby, which intermediate body comprises particularly a part, more particularly the second electrode, of an optically non-active module. By particularly making use here of (a part of) a dummy module as the intermediate body said height difference is seamlessly absorbed, and for the connection of the first conductor use can moreover be made of the same reliable interconnection as used between the other photovoltaic modules.

For a practical integration of the photovoltaic device with the panel a further preferred embodiment of the device has the feature that the photovoltaic device comprises a form-retaining profile with a bottom and opposite legs extending from the bottom and falling over the at least one panel with a tight fit, and that the array of photovoltaic modules is arranged between a bottom of the profile and the exit surface of the at least one panel inside the legs of the profile. Because the profile is form-retaining, i.e. more or less rigid and dimensionally stable, it can be arranged over an end side surface of the at least one panel and be clamped or adhered thereon in relatively simple manner.

For application in an inclining surface, for instance in a skylight in a sloping roof, a particular embodiment of the device here has the feature according to the invention that the optically active frontal side of the array of modules forms an acute angle with the bottom of the profile. The relevant angle can here be adapted to an optimal angle of incidence of the ambient light, particularly from the sun, irrespective of the angle at which the entry surface is oriented here. For an improved watertightness of the whole a further preferred embodiment of the device here has the feature that opposite longitudinal sides of the film assembly are connected to an adjacent leg of the U-profile with interposing of a water barrier, particularly a water barrier comprising a bead of a sealing adhesive paste, more particularly of a silicone paste.

In order to realise an optimal efficiency despite the relatively small area covered by the photovoltaic device, use is preferably made of photovoltaic modules on the basis of photovoltaic cells from a high-quality semiconductor material other than silicon. With this in mind, a further preferred embodiment of the device according to the invention has the feature that the photovoltaic modules comprise one or more cells of a semiconductor material from a group of silicon, gallium arsenide (GaAs), copper indium selenide (CIG), copper indium gallium selenide (CIGS), and particularly comprise copper indium gallium selenide (CIGS) cells. Copper indium gallium selenide or CIGS is a semiconductor material consisting of copper, indium, gallium and selenium. This semiconductor is applied here for the formation of CIGS solar cells in a polycrystalline thin film on a flexible substrate. Such solar cells produce a particularly good conversion efficiency and, if in the right form, can be used very well for the application described here.

A further improvement in efficiency and reduction in cost price is realized with a further preferred embodiment of the device according to the invention, characterized in that the modules each sustain a potential difference of about 0.6 volt between the first conductor and second conductor. Each module thus provides a voltage jump of 0.6 volt, and an array of such modules can be assembled in any multiple thereof by connecting a corresponding number of modules in series. The overall voltage drop over the array can thereby be adapted to for instance an ideal input voltage of a connected load or energy storage, whereby use of a converter can be avoided, and thereby also a conversion loss which would otherwise moreover be caused thereby.

The invention further relates to a photovoltaic device as described above and applied in the device according to the invention, and will now be further elucidated on the basis of an exemplary embodiment and a drawing. In the drawing:

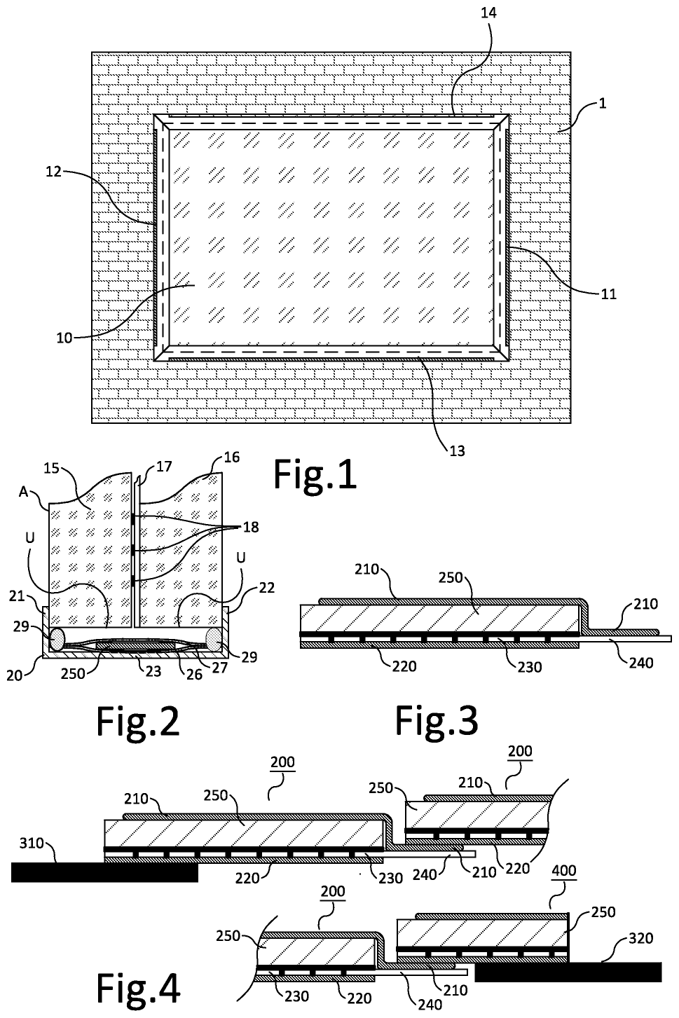

FIG. 1 shows an exemplary embodiment of the device according to the invention in an outer wall of a building;

FIG. 2 shows a cross-section of a photovoltaic device as applied in the device of FIG. 1;

FIG. 3 shows a cross-section of a photovoltaic module as applied in the device of FIG. 2;

FIG. 4 shows one cross-section of an array of interconnected photovoltaic modules of the type as shown in FIG. 3;

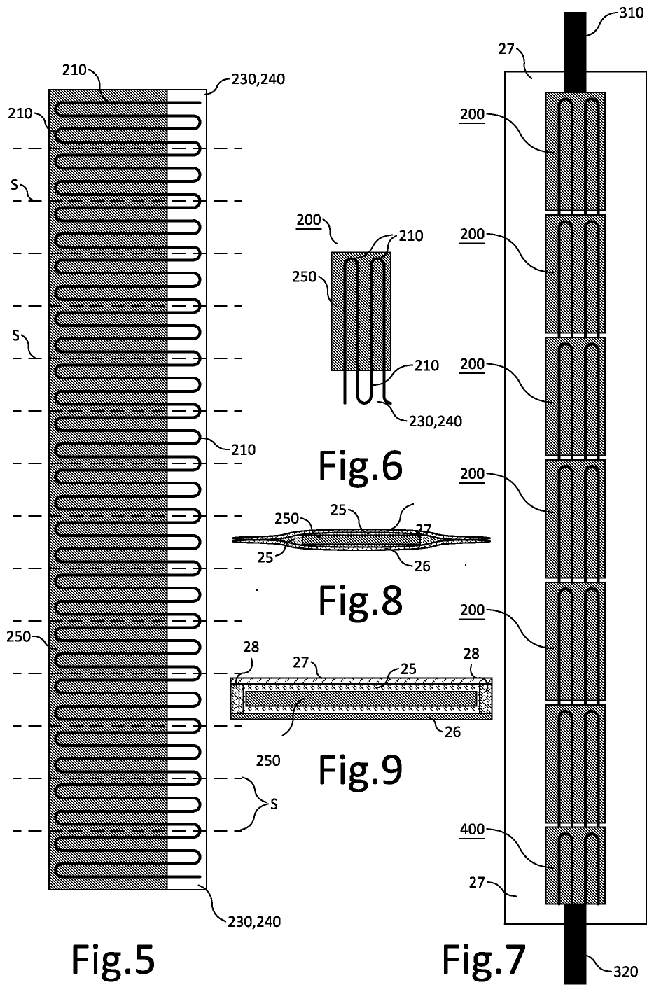

FIG. 5 shows a semi-manufacture from which the photovoltaic module of FIG. 3 was separated;

FIG. 6 shows a top view of the photovoltaic module of FIG. 3;

FIG. 7 shows a top view of the photovoltaic device applied in the device of FIG. 1;

FIG. 8 shows an airtight assembly of a photovoltaic device between a set of films for application in the device according to the invention; and

FIG. 9 shows an alternative assembly of a photovoltaic device between a set of films.

It is otherwise noted here that the figures are purely schematic and not always drawn to (the same) scale. Some dimensions in particular may be exaggerated to greater or lesser extent for the sake of clarity. Corresponding parts are designated in the figures with the same reference numeral.

FIG. 1 shows a typical application of a device for generating energy from ambient light, wherein the device is integrated in or with a window 10 in an outer wall 1 of a building. In this embodiment the device takes a three-fold form here, i.e. a device 11 on the left-hand side, a device 12 on the right-hand side, and a device 13 on a lower side of window 10. Provided in the window is laminated glazing 15, 16, 17 with a first transparent glass panel 15 and a second transparent glass panel 16, and arranged therebetween a transparent film 17, for instance of polyester, see also FIG. 2. A luminescent structure of luminescent domains 18 lies on the film. This structure typically has a degree of coverage of between 20% and 100% of individual dots 18.

Luminescent dots 18 each comprise a luminescent dye which has the ability to absorb primary radiation of a first wavelength and thereupon emit secondary radiation of a second wavelength, referred to here as emission radiation. This phenomenon is based on the mechanism where the dye in question is excited to a higher energy band by the primary radiation and then drops to a lower energy level while emitting photons of the second, usually longer wavelength. In the present application a dye is here preferably chosen, wherein the first and second wavelength lie removed from each other in order to prevent so-called self-absorption (of the second radiation). The dye applied here comprises BASF Lumogen® F RED305 and is able to absorb primary radiation of a wavelength of around 578 nm and emit emission radiation of 615 nm. Both wavelengths lie in the part of the spectrum visible by human perception.

The configuration shown in FIG. 1 comprises a relatively large lateral area A, see FIG. 2, which provides an entry window for ambient light, particularly daylight, incident thereon. This radiation will partially be allowed to pass through glazing 15, 16 unimpeded, namely between dots 18, and partially be absorbed by dots 18. The emission radiation resulting herefrom is emitted more or less omnidirectionally and will thereby partially enter one of the panels 15, 16. If the entry angle is here smaller than the critical angle of the panel, this radiation will be captured in the relevant panel 15, 16 by total internal reflection (TIR) and then exit at an end side surface of the panel.

The end side surfaces thus each form an exit surface U which lies optically in line with one of the photovoltaic devices 11, 12, 13 arranged here according to the invention. These devices 11, 12, 13 each comprise a form-retaining U-profile 20, for instance of a light metal such as aluminium or a form-retaining plastic, with opposite legs 21, 22 between which a photovoltaic conversion device 250 is arranged, comprising an array of photovoltaic modules. In this case conversion device 250 lies here parallel to a bottom 23 of the U-profile in the case of both lateral devices 11, 12, see also FIG. 2, but in the case of device 13 on the lower side forms an angle with the bottom 23 in order to also be able to capture sufficient sunlight when the sun is low.

In order to be able to optimally protect conversion device 250 from air and moisture from the surrounding area, which could otherwise have a highly adverse effect on the performance and lifespan thereof, conversion device 250 lies enclosed hermetically sealed between two transparent barrier films 26, 27 of polyethylene terephthalate (PET), which are both airtight and vapour-tight. Films 26, 27 are laminated on each other with interposing of conversion device 250 with a hydrophobic adhesion 25 which encapsulates the conversion device and thereby additionally seals it, see also FIG. 8. In order to also keep out as much external moisture as possible a bead 29, see FIG. 2, of a suitable sealant (mastic) is arranged along the side edges of lamination 250, 26, 27 over the whole length, which also provides for an adhesion in the U-profile 20.

An alternative assembly of photovoltaic device 250 is shown in FIG. 9. In this case conversion device 250 also lies encapsulated between two PET films 26, 27 with interposing of a hydrophobic adhesive 25 which encapsulates the conversion device. In this case an optically transparent PET film 27 is applied on the optically active side, while an optically dense, black, at least dark, PET film 26 lies on the back side for the purpose of corresponding therewith to the material and appearance of conversion device 250, which also has a dark colour. Device 250 is flanked by an edge seal 28. For this purpose an adhesive strip or bead 28 of polyisobutylene butyl rubber (Quanex Solargain Edge Tape SET LP03) is used, which prevents or at least inhibits penetration of moisture and air and thus helps protect conversion device 250 against corrosion and degradation. The application of such an edge seal 28 allows a more compact construction of stack 26,250,27, and thereby more useful photovoltaic area for enhancing an efficiency of the device.

In order to utilize the available area U as much as possible, the highest possible packing density is strived for in respect of the conversion device. Use is for this purpose made in this embodiment of a conversion device on the basis of an array of interconnected modules, one of which is shown in cross-section in FIG. 3. This is a photovoltaic semiconductor body 250 in which one or more photovoltaic cells together form the module 200 with an operative potential jump in the order of about 0.6 volt. By interconnecting more or fewer of such modules in series a device can thus be realized with an operating voltage of a multiple of 0.6 volt. In this embodiment six of such modules in an array are connected in series in order to realise an output voltage of a total of 3.6 volt, which is thereby optimally adapted to an operating voltage of a user coupled thereto, such as a battery cell, and thereby makes a voltage converter unnecessary.

Use is for this purpose made in this embodiment of a semiconductor body of polycrystalline copper indium gallium selenide or CIGS. This is a semiconductor material of copper, indium, gallium and selenium. The general chemical formula is CulnxGa(1-x)Se2. This material is applied in the form of a thin layer (1.5-2.5 μm) on a flexible polyamide film 210 as substrate, which was for this purpose coated with a fine layer (0.3-0.4 μm) of molybdenum. Layers of cadmium sulphide and zinc oxide are typically also applied to the CIGS layer. On an optically active side each module 200 has a first conductor 210, see FIG. 3. This is a metallization from the semiconductor process, whereby device 250 was also realized. This is deposited on semiconductor material 250 as a meandering conductor path, see also FIG. 5. On a back side film 230 has a flexible metal layer 220 of stainless steel, this serving as second conductor. This second conductor lies here roughly at the position of the semiconductor body 250 of the whole surface of semiconductor body 250 and is connected electrically to a back metallization (not further shown) of semiconductor body 250. Each module is thus electrically connected between the first conductor path 210 on the frontal side of module 200 and the full-surface second conductor 220 on the back side of film 230.

Adjacently of semiconductor body 250 the film 230 comprises a connecting zone 240 which is left clear by the second conductor 220 but over which the first conductor 210 does extend, see also FIG. 4. Successive modules 200 in the array can thus be connected to each other in series in relatively simple manner by stacking a successive module 200 with its full-surface second (back) conductor 220 in connecting zone 240 on the conductor path 210 of the first conductor of the previous module, see FIG. 4. A thus created pressure contact suffices in this overlap for an effective electrical contact, which can optionally be strengthened by means of a short heating step and/or an electrically conductive paste applied therebetween. What is important is that almost no optically active surface area is lost at the position of connecting zone 240 owing to an almost seamless connection of successive modules relative to each other.

An extremely high degree of coverage can also be achieved externally by thus interconnecting a number, geared thereto, of modules over a longitudinal dimension of the relevant device 11, 12, 13, or a height or width of window 10, in one or more of such arrays, for instance always in arrays of six for an output voltage of about 3.6 volt, wherein individual arrays are connected in parallel. Each such array is provided with external connecting electrodes 310, 320 by connecting a metal strip, in this case silver-plated copper, to back conductor 220 of a first outermost module in the array. At the opposite outermost module of the array a (part of a) non-operative intermediate module 400 is used as dummy in order to bridge a difference in level with conductor path 210 on the frontal side. By making use of a part of a non-active module or a whole module, more particularly its second electrode 220, a second connecting electrode 320 can here be arranged, for instance soldered or electrically conductively adhered, in a common plane with the first connecting electrode 310 in similar manner. An all but optimal adaptation is thus possible of a length dimension of the photovoltaic device to a corresponding dimension of the exit surface U of panel 15 . . . 17.

In order also to fit optimally in a width direction of panel 15 . . . 17 with the dimensions of exit surface U corresponding thereto, while the semiconductor modules 200, 400 can otherwise be manufactured in a generic semiconductor process, use is advantageously made of the semi-manufacture shown in FIG. 5. This semi-manufacture comprises the polymer film 230 as transparent, flexible substrate on which the conversion device 250 with the top metallization 210 is arranged as shown in the cross-section of FIG. 3. The meandering top metallization 210 has a pitch of about 6.6 millimetres. This semi-manufacture also comprises at the position of semiconductor material 250 the second conductor on the back side over the whole surface, wherein a contact zone 240 is left clear thereby to the side. The second conductor comprises here a metal layer of stainless steel which was assembled into a laminate together with the film in a roll-to-roll calendering process. This semi-manufacture comprises a strip with a length in the order of for instance 200-400 millimetres by a width in the order of 50-70 millimetres. Contact zone 240 is about 10-15 millimetres wide. The semi-conductor material takes up the other 35-60 millimetres of the width of the strip. The strip applied here has a length of 312 millimetres by a width of 56.5 millimetres.

In order to form modules 200 the strip is separated, for instance cut with scissors or a blade, along the separating lines S, whereby individual modules are separated therefrom, one of which is shown in FIG. 6. The mutual pitch of the separating lines can here be adapted relatively effectively to the available width inside the U-profile 20 of the device, taking into account space for the barrier films 26, 27. In respect of intermediate space between the opposite legs 21, 22 the U-profile will in turn be adapted to the size of the end side surfaces of panel assembly 15 . . . 17 and thereby to a width of the exit window U. In this case a set of modules with a width of between 10 and 15 millimetres is thus separated from the strip of FIG. 5 in this way and, as shown in FIG. 4, interconnected into an array. This array is then provided with connecting electrodes 310, 320 and laminated with the barrier films 26, 27 into the assembly shown in FIG. 7 with interposing of a dummy module 400.

Besides secondary emission radiation from luminescent domains 18, sunlight will also be incident directly on the modules during daylight, which contributes significantly to the overall efficiency of the devices 11 . . . 13 arranged along the edges. Because this component will not or hardly be present on an upper side, a light source 14 which emits artificial light with at least roughly the wavelength of the primary radiation can for instance be applied there. For this light source use can for instance be made of light-emitting diodes (LEDs) distributed over the width of device 14 or a diffusing optical fibre from which exits light originating from a laser at an entrance thereof. A suitable candidate for this is for instance the Corning® Fibrance™ Light Diffusing Fiber. The luminescent domains 18 will also become excited hereby and emit secondary emission radiation. The omnidirectional emission radiation will partially be emitted perpendicularly of window 10 and exceeding the critical angle of the panels and will exit entry surface A at the position of the domains 18, and be visible as light in that form. By arranging the domains optionally in a determined pattern on film 17 a more or less uniform lighting effect or a specific image or text can be projected thereby. This can for instance be used in the evening and at night, at least during darkness, as background lighting or auxiliary lighting and for instance as advertising message or warning signal.

The electric power supply necessary for this lighting can advantageously be drawn from a rechargeable source which was fed by the photovoltaic devices 11 . . . 13 during daylight and as such is coupled thereto as load. The shown system is thereby wholly self-sufficient. This same decentral power supply can also be utilized decentrally, i.e. separately from for instance an electricity grid, as local power supply for environmental sensors and actors which are applied in or at window 10. A smart home or other smart building can thus be realized without electrical power for sensors, actors and/or control units involved therein having to be drawn from a central point, such as for instance a distributor of the electricity grid.

Although the invention has been further elucidated above with reference to only several exemplary embodiments, it will be apparent that the invention is by no means limited thereto. On the contrary, many variations and embodiments are still possible within the scope of the invention for a person with ordinary skill in the art.

Use is thus made in the embodiment of a layered panel of two window panes with a film in which a luminescent structure is arranged therebetween. Instead, more or fewer window panes can also be applied, and the luminescent structure can optionally also be provided directly on the glazing of a panel.

Use is made in the embodiment of a window in a stone outer wall. The application of the invention is however particularly effective in outer walls made completely of glass, so that almost a whole surface area of an outer wall can be utilized in the form of a collection of luminescent solar concentrators for photovoltaic conversion. The invention can however also be applied outside the scope of an LSC as a particularly cost-effective and scalable solution for providing a window with a photovoltaic conversion device in an edge thereof.

The invention is however applicable not only in combination with glass, but one or more of the at least one panel can also be manufactured from a different transparent material, such as for instance a clear plastic such as polycarbonate and poly(methyl methacrylate) (PMMA).

Within the scope of the invention a panel is understood to mean an optionally rigid and optionally flat body with lateral dimensions significantly greater than a thickness thereof in transverse direction. The panel can here for instance also be flexible and/or concave or convex, instead of merely a flat, form-retaining window pane of for instance glass or plastic.

1. A device for generating energy from ambient light, particularly from sunlight, comprising at least one at least substantially transparent panel having on a frontal side a lateral entry surface for ambient light and having laterally of the entry surface, particularly substantially transversely thereof, at least one exit surface which is optically coupled to a photovoltaic conversion device, wherein the conversion device comprises an associated array of mechanically interconnected photovoltaic modules, each comprising one or more photovoltaic cells, a first conductor and a second conductor, in that in each of the photovoltaic modules the one or more photovoltaic cells are electrically connected between the first conductor on an optically active frontal side of the relevant module and the second conductor on an opposite, back side of the relevant module, and that successive modules in the array of modules partially overlap each other such that a first conductor of one module and a second conductor of a subsequent module make contact with each other.

2. The device according to claim 1, wherein a photoluminescent structure of photoluminescent domains is arranged between the entry surface and the exit surface, which domains are able and configured to emit emission radiation upon excitation by primary radiation incident thereon, and to couple at least part of this emission radiation optically into the at least one panel, wherein the emission radiation propagates at least partially to the exit surface and to the conversion device due to total internal reflection.

3. The device according to claim 1, wherein a width of each of the modules is adapted to a width of the at least one exit surface, and that a length of the array of modules is adapted to a length of the at least one exit surface.

4. The device according to claim 1, wherein each of the modules makes use of a carrier substrate, particularly a flexible carrier film, on which the one or more photovoltaic cells are arranged, in that the carrier substrate comprises beyond the one or more photovoltaic cells a contact zone over which the first conductor of the module extends, and in that the module overlaps in the contact zone with an adjacent module in the array.

5. The device according to claim 4, wherein successive modules in the array of modules are mutually stacked at the position of the overlap for the purpose of forming a pressure contact between the first conductor and the second conductor of the successive modules.

6. The device according to claim 1, wherein the photovoltaic conversion device comprises a moisture-tight film assembly, comprising an optically clear first barrier film on an optically active side of the array of modules and a second barrier film on an opposite, back side of the array of modules, and in that the first and second barrier film extend laterally outside the array of modules, particularly all the way around, and are mutually connected at the position of a mutual overlap in order to enclose the array of modules in at least substantially vapour-tight manner.

7. The device according to claim 1, wherein the photovoltaic conversion device comprises a moisture-tight film assembly, comprising an optically clear first barrier film on an optically active side of the array of modules and a second barrier film on an opposite, back side of the array of modules, that the array of modules is flanked on either side, by an edge seal and lies enclosed together therewith between the films in order to enclose the array of modules in at least substantially vapour-tight manner.

8. The device according to claim 6, wherein each of the films comprises a plastic film, particularly an optically clear polyethylene terephthalate (PET) film on the optically active side and an optically dark polyethylene terephthalate (PET) film on the back side.

9. The device according to claim 6, wherein the barrier films and the array of modules are mutually adhered with interposing of an optically clear and hydrophobic adhesive.

10. The device according to claim 1, wherein a first module in the array of modules and a final module of the array of modules are each provided with a connecting electrode, wherein the connecting electrode of the first module and that of the final module each lie on a back side of the array of modules.

11. The device according to claim 10, wherein one of the connecting electrodes is connected via a conductive intermediate body to the first conductor of the module connected thereby, which intermediate body comprises particularly a part, more particularly the second electrode, of an optically non-active module.

12. The device according to claim 1, wherein the photovoltaic device comprises a form-retaining profile with a bottom and opposite legs extending from the bottom and falling over the at least one panel with a tight fit, and that the array of photovoltaic modules is arranged between a bottom of the profile and the exit surface of the at least one panel inside the legs of the profile.

13. The device according to claim 12, wherein an optically active surface on the optically active frontal side of the array of modules forms an acute angle with the bottom of the profile.

14. The device according to claim 12, wherein opposite longitudinal sides of the film assembly are connected to an adjacent leg of the U-profile with interposing of a water barrier, particularly a water barrier comprising a bead of a sealing adhesive paste, more particularly of a silicone paste.

15. The device according to claim 1, wherein the photovoltaic modules comprise one or more cells of a semiconductor material from a group of silicon, gallium arsenide (GaAs), copper indium selenide (CIG), copper indium gallium selenide (CIGS), and particularly comprise copper indium gallium selenide (CIGS) cells.

16. The device according to claim 1, wherein the modules each sustain a potential difference of about 0.6 volt between the first conductor and second conductor.

17. A photovoltaic conversion device as applied in the device according to claim 1.
